(19) United States
(12) Patent Application Publication
(10) Pub. No.: US 2016/0327613 A1
(43) Pub. Date: Nov. 10, 2016

(54) BATTERY STATE ESTIMATING DEVICE AND POWER SUPPLY DEVICE

(71) Applicant: PANASONIC INTELLECTUAL PROPERTY MANAGEMENT CO., LTD., Osaka-shi (JP)

(72) Inventors: HIROSHI TENMYO, Osaka (JP); SHIN-ICHI YUASA, Kyoto (JP)

(21) Appl. No.: 15/110,171

(22) PCT Filed: Jan. 16, 2015
(86) PCT No.: PCT/JP2015/000173

§ 371 Date: Jul. 7, 2016

(30) Foreign Application Priority Data
Jan. 29, 2014 (JP) 2014-014037

(51) Int. Cl. G01R 31/36; H02J 7/00; H01M 10/44

(52) U.S. Cl. CPC G01R 31/3651; G01R 31/3662; H01M 10/446; H01M 10/448; H02J 7/008

(57) ABSTRACT

Internal resistance estimating part estimates internal resistance R of a secondary battery. SOH_R calculating part calculates SOH_R based on estimated internal resistance R. Storage stores an SOH_R-SOH_C table. SOH_C calculating part calculates SOH_C based on calculated SOH_R with reference to the SOH_R-SOH_C table. FCC estimating part estimates FCC based on calculated SOH_C.

### TECHNICAL FIELD

The present invention relates to a battery state estimating device and a power supply device.

### BACKGROUND ART

A backup power supply device is known which includes a secondary battery, such as a lithium ion battery, and which supplies electric power from the secondary battery when commercial alternating current power supply fails. In order to prevent the secondary battery from being overdischarged or overcharged, accurate calculation of full charge capacity of the secondary battery is desired. However, the secondary battery used in the backup power supply device is often held in a full charge state, and the full charge capacity may be undetectable due to perfect discharge or charge. According to one conventional method, the full charge capacity is calculated based on a change rate of a state of charge (SOC) (also referred to as a charging rate) of the secondary battery detected at timing at which the secondary battery becomes no-load, and an amount of change in a charge and discharge current integrated value (refer to PTL 1 below).

### CITATION LIST

### Patent Literature

PTL 1: Unexamined Japanese Patent Publication No. 2006-155915

### SUMMARY OF THE INVENTION

A battery state estimating device according to the present invention includes: a first estimating part that estimates internal resistance of a secondary battery at predetermined timing; a first calculating part that calculates a first ratio of the internal resistance of the secondary battery in an initial state to the internal resistance of the secondary battery at the predetermined timing; a storage that stores associated data that associates an internal resistance ratio which is a ratio of the internal resistance of the secondary battery in the initial state to the internal resistance of the secondary battery in a degraded state with a full charge capacity ratio which is a ratio of a full charge capacity of the secondary battery in the initial state to the full charge capacity of the secondary battery in the degraded state; and a second estimating part that estimates the full charge capacity of the secondary battery at the predetermined timing based on the first ratio calculated by the first calculating part with reference to the associated data.

The above configuration makes it possible to provide the battery state estimating device and power supply device capable of calculating the full charge capacity of the secondary battery easily in a short time.

### BRIEF DESCRIPTION OF DRAWINGS

FIG. 1 is a diagram illustrating a power supply device according to a first exemplary embodiment of the present invention.

FIG. 2 is a conceptual diagram illustrating correspondence between an internal resistance ratio and a full charge capacity ratio.

FIG. 3 is a table diagram describing the correspondence between the internal resistance ratio and the full charge capacity ratio.

FIG. 4 is a diagram illustrating a configuration example of a state detector according to the first exemplary embodiment of the present invention.

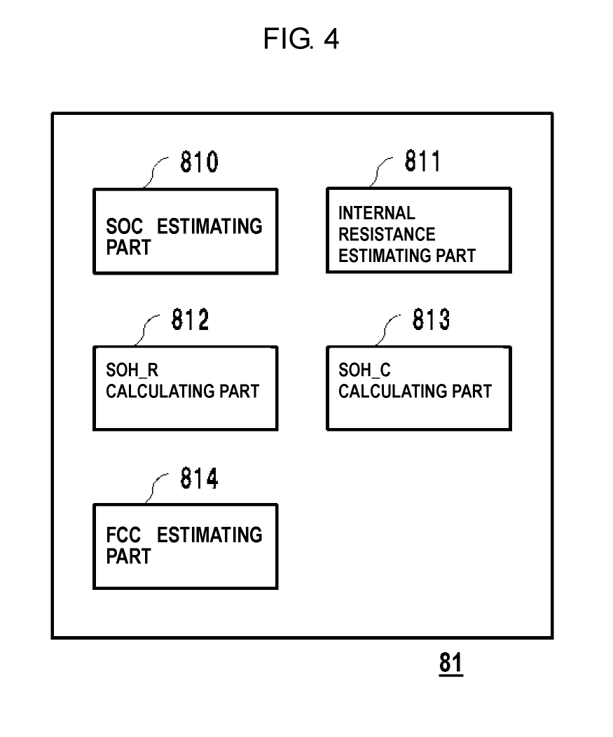

FIG. 5 is an operational flowchart regarding estimation of a full charge capacity according to the first exemplary embodiment of the present invention.

FIG. 6 is a diagram illustrating the power supply device according to a second exemplary embodiment of the present invention.

FIG. 7 is an operational flowchart regarding breaking-in charge and discharge during a storage period of a secondary battery according to the second exemplary embodiment of the present invention.

### DESCRIPTION OF EMBODIMENTS

Prior to description of the exemplary embodiments of the present invention, problems of a conventional battery state estimating device and a power supply device will be described.

A conventional method of calculating a full charge capacity of a secondary battery is based on a rate of change in SOC of the secondary battery detected at timing at which the secondary battery becomes no-load, and an amount of change in a charge and discharge current integrated value. Therefore, according to the conventional method, since the secondary battery is no longer no-load when commercial alternating current power supply fails and electric power starts to be supplied from a backup power supply device, the full charge capacity may not be calculated. In addition, according to the conventional method, it is necessary to detect the rate of change in SOC at timing at which the secondary battery becomes no-load and the amount of change in the charge and discharge current integrated value, which may lead to longer time required for calculation.

The following describes the battery state estimating device and the power supply device capable of calculating the full charge capacity of the secondary battery easily in a short time.

### First Exemplary Embodiment

An example of the first exemplary embodiment of the present invention will be specifically described with reference to the drawings. In each referenced drawing, identical symbols are used to refer to identical components, and duplicate description regarding the identical components will be omitted in principle.

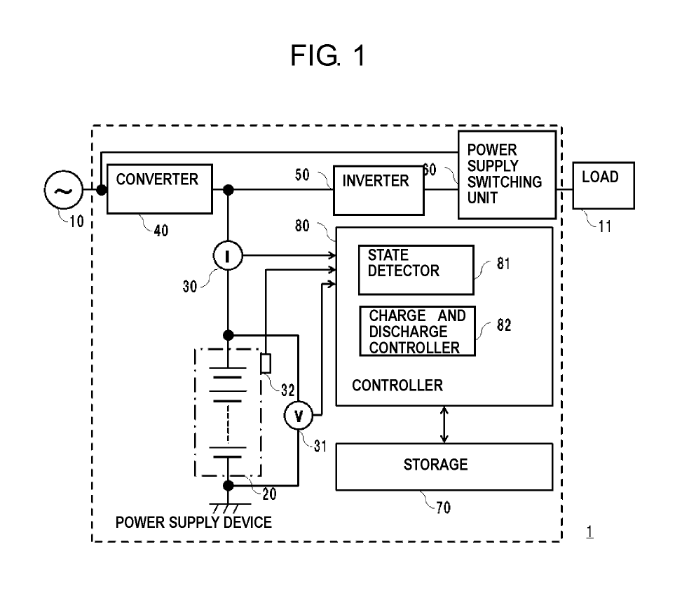

FIG. 1 is a diagram illustrating power supply device 1 according to the first exemplary embodiment of the present invention. According to the first exemplary embodiment, power supply device 1 is assumed to be a backup power supply device connected to commercial alternating current power supply 10 for supplying alternating current power to load 11 when commercial alternating current power supply 10 fails. Power supply device 1 includes battery module 20, current sensor 30, voltage sensor 31, temperature sensor 32, converter 40, inverter 50, power supply switching unit 60, storage 70, and controller 80.

Battery module 20 includes one or more secondary batteries. The secondary batteries included in battery module 20 are, for example, a lithium ion battery or a nickel metal hydride battery. In FIG. 1, although battery module 20 includes a plurality of secondary batteries connected in series, battery module 20 may include one secondary battery. In addition, part or all of the secondary batteries included in battery module 20 may be connected in parallel with each other. According to the first exemplary embodiment, discharge and charge mean discharge and charge of battery module 20 unless otherwise specified.

Current sensor 30 (for example, a shunt resistor and a Hall element) is disposed between battery module 20, converter 40, and inverter 50, and measures current value Id of a current that flows through battery module 20. Current sensor 30 outputs detected current value Id to controller 80.

Voltage sensor 31 detects voltage value Vd of a terminal voltage of each of the plurality of secondary batteries (a potential difference between a positive electrode and negative electrode of each of the plurality of secondary batteries) that constitute battery module 20. Voltage sensor 31 outputs detected voltage value Vd of each secondary battery to controller 80.

Temperature sensor 32 (for example, a thermistor) detects temperature Td of battery module 20 (for example, surface temperature of battery module 20). Temperature sensor 32 outputs detected temperature Td to controller 80.

In accordance with an instruction from controller 80, converter 40 converts alternating current power supplied from commercial alternating current power supply 10 into direct current power, and then supplies the direct current power to battery module 20 to charge battery module 20. In charging, converter 40 manages a charging voltage and a charging current in accordance with an instruction from controller 80.

In accordance with an instruction from controller 80, inverter 50 discharges battery module 20, converts direct current power supplied from battery module 20 into alternating current power, and then supplies the alternating current power to power supply switching unit 60. In discharging, inverter 50 manages a discharging voltage and a discharging current in accordance with an instruction from controller 80. Note that it can also be considered that converter 40 and inverter 50 constitute a power converter of power supply device 1.

Power supply switching unit 60 receives supply of alternating current power from commercial alternating current power supply 10. In addition, power supply switching unit 60 receives supply of alternating current power from inverter 50. Furthermore, in accordance with an instruction from controller 80, power supply switching unit 60 selects one of the alternating current power supplied from commercial alternating current power supply 10 and the alternating current power supplied from inverter 50, and then supplies the selected alternating current power to load 11.

Storage 70 holds and stores a program to be executed by controller 80 and data to be used by the program. For example, storage 70 holds and stores SOC, SOH, FCC, etc. which are calculated and estimated by state detector 81. Furthermore, storage 70 includes an SOC-OCV table and an SOH_R-SOH_C table.

The SOC-OCV table is a table that describes a relationship between SOC of the secondary battery and an open circuit voltage (OCV) (also referred to as open voltage) of the secondary battery. The SOC-OCV table is generated, for example, from data of SOC and OCV acquired by previous experiment or simulation when the secondary battery is gradually charged from a state where a charging rate of the secondary battery is 0%.

The SOH_R-SOH_C table is a table that describes a relationship between a state of health_resistance (SOH_R), which is a ratio of internal resistance in an initial state of the secondary battery to the internal resistance in a degraded state of the secondary battery, and a state of health_capacity (SOH_C), which is a ratio of a full charge capacity (FCC) in the initial state of the secondary battery to FCC in the degraded state of the secondary battery. Here, the initial state refers to a state where the secondary battery is not degraded, and for example, refers to a state immediately after the secondary battery is manufactured. In addition, the degraded state refers to a state where the secondary battery is degraded, and for example, refers to a state after the secondary battery is charged or discharged. The SOH_R-SOH_C table is generated from data of SOH_R and SOH_C acquired when the secondary battery is gradually degraded from the initial state by previous experiment or simulation. A detailed configuration example of the SOH_R-SOH_C table will be described later.

Controller 80 manages power supply device 1 as a whole. For example, when an abnormality occurs in commercial alternating current power supply 10, such as a power failure, controller 80 instructs power supply switching unit 60 to switch alternating current power to be supplied to load 11 to alternating current power supplied from inverter 50. In addition, when commercial alternating current power supply 10 recovers, controller 80 instructs power supply switching unit 60 to switch alternating current power to be supplied to load 11 to alternating current power supplied from commercial alternating current power supply 10.

In addition, controller 80 includes state detector 81 and charge and discharge controller 82. State detector 81 detects SOC, SOH, FCC, and the like of the secondary battery by using battery state data including current value Id received from current sensor 30, voltage value Vd received from voltage sensor 31, and temperature Td received from temperature sensor 32. Based on SOC and the like detected by state detector 81 and a user operation, charge and discharge controller 82 causes converter 40 to perform charge control, or causes inverter 50 to perform discharge control. In addition, charge and discharge controller 82 stores SOC, SOH, FCC, and the like received from state detector 81 in storage 70 at timing at which discharge or charge of battery module 20 is stopped or started. Furthermore, charge and discharge controller 82 stops discharge or charge of battery module 20, and then measures elapsed time after starting storage of battery module 20 with a timer or the like. Note that it can also be considered that power supply device 1 includes the battery state estimating device including storage 70 and state detector 81.

Prior to specific description of state detector 81, a summary of an operation of estimating FCC to be performed by state detector 81 will be described.

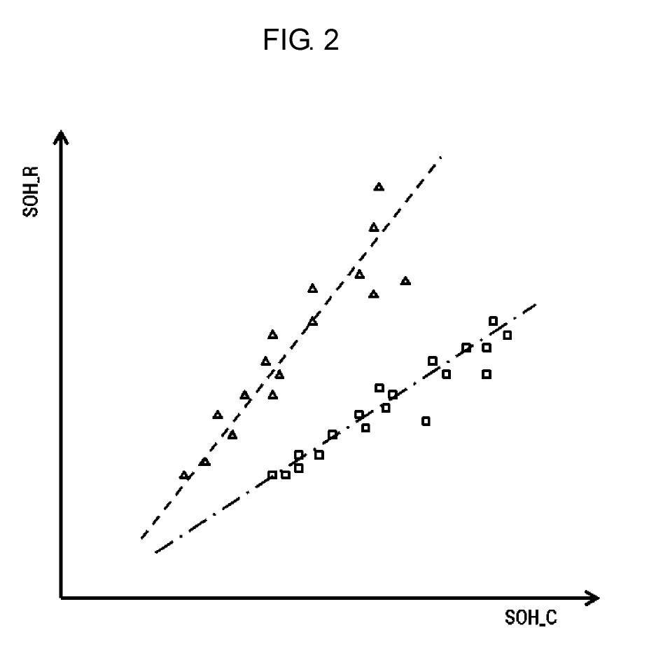

FIG. 2 is a conceptual diagram illustrating correspondence between SOH_R and SOH_C. Points illustrated as triangles in FIG. 2 plot (SOH_R, SOH_C) determined for each of the plurality of secondary batteries with different degradation degrees, the secondary batteries being produced by charging the secondary batteries in the initial state to a predetermined charging rate (SOC a %) and storing the secondary batteries while changing a storage condition such as temperature and period. In addition, points illustrated as squares plot (SOH_R, SOH_C) determined for each of the plurality of secondary batteries with different degradation degrees, the secondary batteries being produced by charging the secondary batteries in the initial state to the charging rate lower than SOC a % (SOC b %) and storing the secondary batteries while changing the storage condition similarly.

As illustrated in FIG. 2, there is a correlation between SOH_R and SOH_C which are determined from the secondary batteries with different degradation degrees, and a linear function (also referred to as just a characteristic function) can be applied as a relational expression. This characteristic function can be previously determined by performing regression operation or the like on data obtained by previous experiment. If SOH_R is determined, SOH_C can be determined by application of SOH_R to this characteristic function. Since FCC in the initial state is already known, FCC can be determined from SOH_R by using the characteristic function.

When determining FCC directly, for example, it is necessary to discharge or charge the secondary battery for a certain period, and to detect the rate of change in SOC and the amount of change in discharge current integrated value. Accordingly, accuracy of FCC is dependent on magnitude of the rate of change in SOC. Therefore, direct determination of FCC may lead to longer required time. In contrast, SOH_R is determined by estimating internal resistance, and the internal resistance can be determined in a relatively short time with reference to map information previously determined.

Therefore, according to the first exemplary embodiment of the present invention, SOH_R is determined from the estimated internal resistance, and FCC is determined by application of SOH_R to the characteristic function. This allows FCC to be determined easily and in a short time as compared with direct determination of FCC. The first exemplary embodiment of the present invention assumes to prescribe the correspondence of the characteristic function by writing the SOH_R-SOH_C table that associates SOH_R with SOH_C.

Meanwhile, as illustrated in FIG. 2, different correspondence is illustrated between the characteristic function acquired when the secondary battery is stored at SOC a % (for example, SOC 100%) (the characteristic function is illustrated by a dotted line in FIG. 2 and is also referred to as a first characteristic function), and the characteristic function acquired when the secondary battery is stored at SOC b % lower than SOC a % (for example, SOC 50%) (the characteristic function is illustrated by an alternate long and short dash line in FIG. 2 and is also referred to as a second characteristic function). Accordingly, when estimating FCC by applying SOH_R to the characteristic function, in order to improve estimation accuracy of FCC, it is desired to select the characteristic function suitable for SOC when the secondary battery is stored.

Therefore, the SOH_R-SOH_C table according to the first exemplary embodiment of the present invention includes amounts of correction for correcting the correspondence of the characteristic function in accordance with magnitude of SOC when the secondary battery is stored. Accordingly, the correspondence between SOH_R and SOH_C suitable for a length of a storage period of the secondary battery can be prescribed, and the estimation accuracy of FCC can be improved.

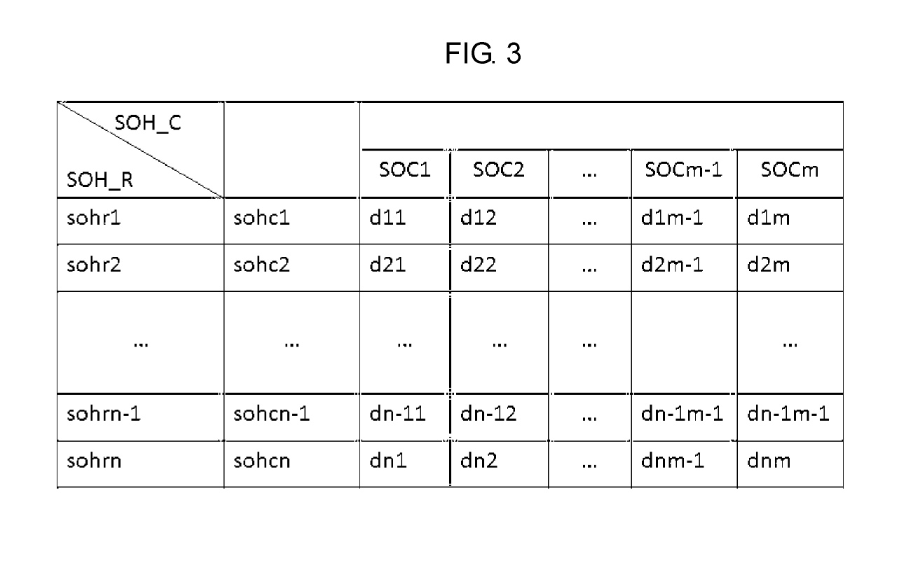

As illustrated in FIG. 3, the SOH_R-SOH_C table describes SOH_C to be associated with SOH_R in a combination of reference values and the amounts of correction according to the magnitude of SOC when the secondary battery is stored. SOH_R fields describe n SOH_R values sohri (i is an integer from 1 to n). SOH_C fields describe SOH_C to be associated with sohri in a combination of reference values sohci and m amounts of correction dij (j is an integer from 1 to m) according to the magnitude of SOC (SOC1<SOC2< . . . <SOCm-1<SOCm) when the secondary battery is stored. With reference to the SOH_R-SOH_C table by using the value sohri of SOH_R and SOCj when the secondary battery is stored, the reference values sohci and the amounts of correction dij of corresponding SOH_C can be determined. Then, by adding the amounts of correction dij to the reference values sohci, the correspondence between SOH_R and SOH_C can be corrected in accordance with the magnitude of SOC when the secondary battery is stored.

State detector 81 based on the above configuration will be specifically described below. State detector 81 includes SOC estimating part 810, internal resistance estimating part 811, SOH_R calculating part 812, SOH_C calculating part 813, and FCC estimating part 814.

SOC estimating part 810 estimates SOC_i of battery cells by integrating current value Id received from current sensor 30. Specifically, SOC estimating part 810 estimates SOC_i by following Equation (1).

SOC_i=SOC0±(Q/FCC)×100 (1)

where, SOC0 represents SOC prior to start of charge or discharge, Q represents the current integrated value, and FCC represents the full charge capacity. A symbol+represents charge, whereas a symbol—represents discharge. SOC estimating part 810 reads SOC and FCC stored in storage 70, calculates Q by integrating current value Id, and then estimates SOC_i by Equation (1).

In addition, SOC estimating part 810 estimates OCV of each secondary battery from current value Id received from current sensor 30, voltage value Vd of each secondary battery received from voltage sensor 31, and internal resistance R of each secondary battery received from internal resistance estimating part 811. Then, SOC estimating part 810 specifies SOC corresponding to OCV. The first exemplary embodiment assumes to estimate OCV by following Equation (2).

OCV=Vd±Id×R (2)

Note that Equation (2) is one example of the OCV estimating equation, and another estimating equation may be used. For example, an estimating equation with temperature correction introduced may be used.

SOC estimating part 810 specifies SOC_v corresponding to calculated OCV with reference to the SOC-OCV table. Specifically, with reference to the SOC-OCV table, SOC estimating part 810 reads SOC corresponding to calculated OCV.

Then, SOC estimating part 810 determines SOC to be employed from calculated SOC_i and SOC_v. For example, while the secondary battery is not charged or discharged, SOC estimating part 810 employs SOC_v as it is. While the secondary battery is charged or discharged, SOC estimating part 810 employs SOC_i as it is, or employs SOC_i corrected with SOC_v.

Internal resistance estimating part 811 estimates internal resistance R of each secondary battery from current value Id received from current sensor 30 and voltage value Vd of each secondary battery received from voltage sensor 31. The internal resistance value may be specified with reference to map information determined in advance, and may be estimated from an I-V relationship between the current value and voltage value detected during charge or discharge.

SOH_R calculating part 812 calculates SOH_R at predetermined timing t by Equation (3) from internal resistance R of each secondary battery received from internal resistance estimating part 811.

SOH_R=R/Ri (3)

where, Ri represents the internal resistance in the initial state. The first exemplary embodiment assumes to measure Ri by experiment or the like in advance and to store Ri in storage 70.

With reference to the SOH_R-SOH_C table, SOH_C calculating part 813 specifies SOH_C at predetermined timing t from SOH_R of each secondary battery received from SOH_R calculating part 812 and SOC stored in storage 70 when the secondary battery is stored. Specifically, with reference to the SOH_R-SOH_C table, SOH_C calculating part 813 reads the reference value and the amount of correction of SOH_C corresponding to calculated SOH_R and SOC when the secondary battery is stored. When the SOH_R-SOH_C table does not describe calculated SOH_R and SOC when the secondary battery is stored, SOH_C calculating part 813 reads at least two reference values adjacent to calculated SOH_R and at least four amounts of correction adjacent to SOC when the secondary battery is stored. SOH_C calculating part 813 then calculates the reference value and the amount of correction corresponding to calculated SOH_R and SOC when the secondary battery is stored by interpolation. SOH_C calculating part 813 adds the calculated reference value to the amount of correction, and then specifies SOH_C at predetermined timing t.

FCC estimating part 814 estimates FCC at predetermined timing t by following Equation (4) from SOH_C of each secondary battery received from SOH_C calculating part 813.

FCC=SOH_C×FCCi (4)

where, FCCi represents full charge capacity in the initial state. In a similar manner to Ri, the first exemplary embodiment assumes that FCCi is stored in storage 70. FCC estimating part 814 outputs estimated FCC to charge and discharge controller 82.

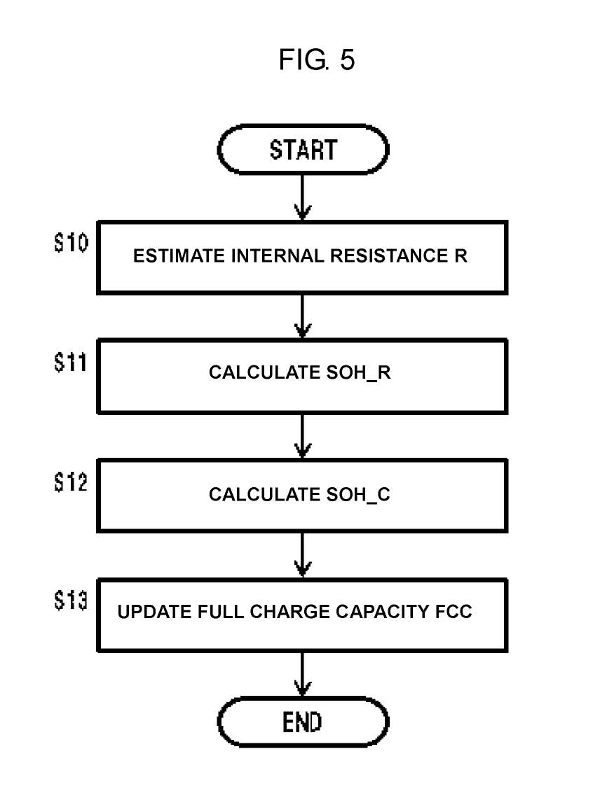

Operations of the battery state estimating device with the above configuration will be described. FIG. 5 is an operational flowchart regarding estimation of a full charge capacity according to the first exemplary embodiment of the present invention. For example, when charge and discharge controller 82 starts control of charge or discharge of battery module 20 in order to supply alternating current power to load 11 via inverter 50, internal resistance estimating part 811 estimates the internal resistance of each secondary battery from current value Id received from current sensor 30 and voltage value Vd received from voltage sensor 31 (S10). SOH_R calculating part 812 calculates SOH_R at predetermined timing by using the internal resistance of each secondary battery estimated by internal resistance estimating part 811 and internal resistance Ri in the initial state read from storage 70 (S11). SOH_C calculating part 813 calculates SOH_C at predetermined timing with reference to the SOH_R-SOH_C table read from storage 70 by using SOH_R calculated by SOH_R calculating part 812 and SOC stored in storage 70 when the secondary battery is stored (S12). FCC estimating part 814 estimates FCC at predetermined timing by using SOH_C calculated by SOH_C calculating part 813, and then charge and discharge controller 82 updates FCC held in storage 70 by using FCC received from FCC estimating part 814 (S13). SOC estimating part 810 reads updated FCC from storage 70 to estimate SOC. Charge and discharge controller 82 continues charge control or discharge control of battery module 20 with reference to SOC or the like received from SOC estimating part 810. Charge and discharge controller 82 stops charge or discharge of battery module 20, and before starting storage of battery module 20, charge and discharge controller 82 updates SOC held in storage 70 by using SOC received from SOC estimating part 810.

According to the first exemplary embodiment of the present invention, internal resistance estimating part 811 estimates internal resistance R of the secondary battery. SOH_R calculating part 812 calculates SOH_R based on estimated internal resistance R. Storage 70 stores the SOH_R-SOH_C table. With reference to the SOH_R-SOH_C table, SOH_C calculating part 813 calculates SOH_C based on calculated SOH_R. FCC estimating part 814 estimates FCC based on calculated SOH_C. Therefore, FCC can be estimated easily and in a short time. FCC estimating part 814 estimates FCC based on SOH_C corrected with the amount of correction included in the SOH_R-SOH_C table. Therefore, FCC can be estimated with good accuracy. SOC estimating part 810 estimates SOC by using FCC updated by FCC estimating part 814. Therefore, even after storage for a long period of time, the charging state of the secondary battery can be known accurately, and the secondary battery can be charged or discharged safely and accurately.

### Second Exemplary Embodiment

The second exemplary embodiment will be described. The second exemplary embodiment describes a modification technique of the technique described in the first exemplary embodiment. Except for charge and discharge of a secondary battery during a storage period and associated description to be given later, configuration and operation of a power supply device according to the second exemplary embodiment are identical to the configuration and operation of the power supply device according to the first exemplary embodiment.

In general, if internal resistance of the secondary battery is measured after the secondary battery is stored for a long period of time, the measured internal resistance may be significantly deviated from a true value. In such a case, when the internal resistance is measured again after the secondary battery is charged and discharged several times, the deviation of the internal resistance from the true value may be reduced.

Therefore, according to the second exemplary embodiment of the present invention, charge and discharge of the secondary battery (also referred to as breaking-in charge and discharge) are performed during a storage period, SOH_R is determined after the deviation of the internal resistance from the true value is reduced, and then FCC is determined by application of SOH_R to a characteristic function. This further improves estimation accuracy of FCC.

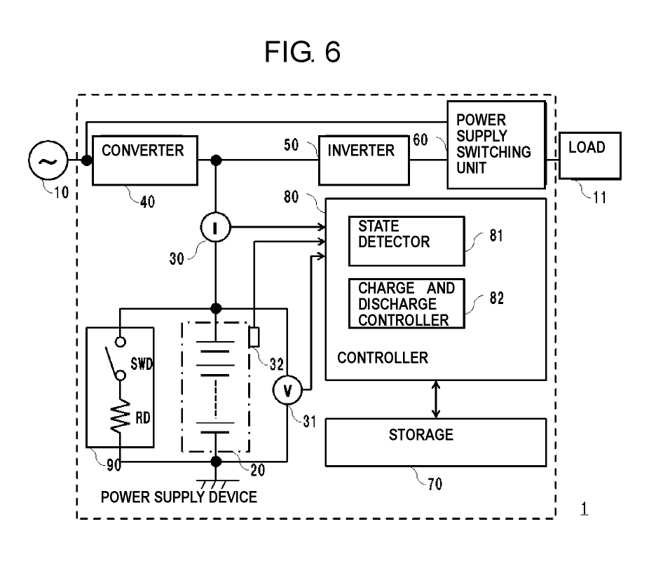

FIG. 6 is a diagram illustrating power supply device 1 according to the second exemplary embodiment of the present invention. Power supply device 1 according to the second exemplary embodiment can be configured by addition of discharge unit 90 to power supply device 1 according to the first exemplary embodiment.

Discharge unit 90 includes switching element SWD and resistive element RD connected in series. As switching element SWD, for example, an n-type metal-oxide-semiconductor field-effect transistor (MOSFET), which is one of semiconductor switches, can be used. Instead of the n-type MOSFET, an insulated gate bipolar transistor (IGBT), gallium nitride (GaN) transistor, silicon carbide (SiC) transistor, and the like may be used. Switching element SWD turns on and off in response to a control signal from charge and discharge controller 82. Discharge unit 90 discharges battery module 20 through resistive element RD by turning on switching element SWD.

Every time a predetermined period elapses during the storage period, charge and discharge controller 82 performs pre-discharge of battery module 20 in order to calculate SOH_R. Specifically, charge and discharge controller 82 performs control to turn on switching element SWD of discharge unit 90, and performs control to turn on an unillustrated switching element so that controller 80 receives electric power supply directly from battery module 20. Charge and discharge controller 82 compares a difference value between SOH_R calculated with this pre-discharge by SOH_R calculating part 812 (also referred to as first SOH_R) and SOH_R stored in storage 70 (also referred to as second SOH_R) with a threshold regarding the difference value (also referred to as a first threshold). When the difference value becomes larger than the first threshold, charge and discharge controller 82 determines that the deviation of measured internal resistance from the true value has become large, performs control to turn on switching element SWD of discharge unit 90, and starts discharge of battery module 20. After discharging battery module 20 to SOC c % (for example, SOC 80%), charge and discharge controller 82 performs control to turn off switching element SWD of discharge unit 90, and controls converter 40 to start charge of battery module 20. After charging battery module 20 to SOC d % (for example, SOC 100%), charge and discharge controller 82 stops charging. Charge and discharge controller 82 repeats a predetermined number of times of such breaking-in charge and discharge control. At every timing at which discharge of breaking-in charge and discharge control is started, the charge and discharge controller acquires SOH_R calculated by SOH_R calculating part 812 and FCC estimated by FCC estimating part 814 based on SOH_R. Then, of the breaking-in charge and discharge control that is repeated the predetermined number of times, by using SOH_R and FCC acquired at timing at which final discharge is started, charge and discharge controller 82 updates SOH_R and FCC held in storage 70.

At timing before stopping charge for each breaking-in charge and discharge control, charge and discharge controller 82 acquires SOH_R calculated by SOH_R calculating part 812 (also referred to as third SOH_R). If the difference value between the first SOH_R and the third SOH_R is smaller than the first threshold, charge and discharge controller 82 may finish the breaking-in charge and discharge control. This allows efficient breaking-in charge and discharge control to be performed. When charge and discharge controller 82 determines whether to continue the breaking-in charge and discharge control for each breaking-in charge and discharge control, if the difference value between the first SOH_R and the third SOH_R is larger than the first threshold even if the prescribed number of times of breaking-in charge and discharge control is performed, charge and discharge controller 82 may not continue but stop the breaking-in charge and discharge control. This is because, when the difference value between the first SOH_R and the third SOH_R is larger than the first threshold, there is a possibility that actual internal resistance becomes large and SOH_R becomes large due to advancement of degradation of the secondary battery during the storage period, not because the deviation of the true value from the measured value of the internal resistance becomes large. This prevents execution of useless breaking-in charge and discharge control.

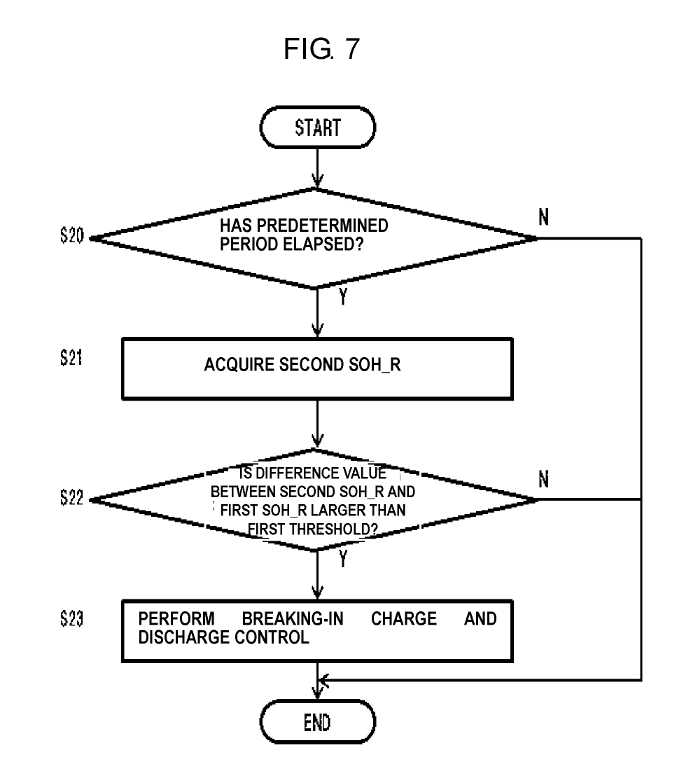

Operations of power supply device 1 with the above configuration will be described. FIG. 7 is an operational flowchart regarding breaking-in charge and discharge during the storage period of the secondary battery according to the second exemplary embodiment of the present invention. Charge and discharge controller 82 measures elapsed time after performing previous charge and discharge control during the storage period, and then determines whether a predetermined period has elapsed (S20). When the predetermined period has elapsed (Y in S20), charge and discharge controller 82 acquires the second SOH_R calculated by SOH_R calculating part 812. Charge and discharge controller 82 compares the difference value between the first SOH_R and the second SOH_R with the first threshold (S22). When the difference value is larger than the first threshold (Y in S22), charge and discharge controller 82 performs the predetermined number of times of breaking-in charge and discharge control (S23). Of the predetermined number of times of repeated breaking-in charge and discharge control, at timing for starting discharge of final breaking-in charge and discharge control, charge and discharge controller 82 acquires SOH_R calculated by SOH_R calculating part 812 and FCC estimated by FCC estimating part 814 based on the SOH_R. Charge and discharge controller 82 updates SOH_R and FCC held in storage 70 by using the acquired SOH_R and FCC.

According to the second exemplary embodiment of the present invention, charge and discharge controller 82 compares, with the first threshold, the difference value between the first SOH_R stored in storage 70 and the second SOH_R calculated by SOH_R calculating part 812. When the difference value becomes larger than the first threshold, charge and discharge controller 82 starts the breaking-in charge and discharge control. Of the predetermined number of times of repeated breaking-in charge and discharge control, at timing for starting discharge of the final breaking-in charge and discharge control, FCC estimating part 814 estimates FCC based on SOH_R calculated by SOH_R calculating part 812. At this timing, charge and discharge controller 82 acquires SOH_R calculated by SOH_R calculating part 812 and FCC estimated by FCC estimating part 814, and then updates SOH_R and FCC stored in storage 70. Therefore, FCC can be estimated with the deviation of the internal resistance from the true value reduced by breaking-in charge and discharge, and estimation accuracy of FCC can be further improved.

### Third Exemplary Embodiment

The third exemplary embodiment will be described. The third exemplary embodiment describes a modification technique of the technique described in the second exemplary embodiment. Except for performing charge if dischargeable capacity of a secondary battery decreases during a storage period and associated description to be given later, configuration and operation of a power supply device according to the third exemplary embodiment are identical to configuration and operation of the power supply device according to the second exemplary embodiment.

In general, when the secondary battery is stored for a long period of time, the dischargeable capacity of the secondary battery may decrease because of self-discharge or the like. In order to supply sufficient electric power to load 11 when an abnormality occurs in commercial alternating current power supply 10, it is preferable to charge the secondary battery when the dischargeable capacity decreases (also referred to as auxiliary charge). Estimation of FCC or the like at this timing before stopping charging makes it possible to estimate FCC while reducing deviation of internal resistance from a true value.

Therefore, according to the third exemplary embodiment of the present invention, charge and discharge controller 82 determines FCC by charging the secondary battery when the dischargeable capacity of the secondary battery decreases during the storage period, determining SOH_R at timing for starting the charge, and applying SOH_R to a characteristic function. This allows further improvement in estimation accuracy of FCC.

For this purpose, every time a predetermined period elapses during the storage period, charge and discharge controller 82 compares SOC estimated by SOC estimating part 810 with a threshold regarding SOC (also referred to as a second threshold). When the estimated SOC becomes smaller than the second threshold, charge and discharge controller 82 determines that the dischargeable capacity has significantly decreased, controls converter 40, and starts charging of battery module 20. At timing for starting charging, charge and discharge controller 82 acquires SOH_R calculated by SOH_R calculating part 812 and FCC estimated by FCC estimating part 814 based on the SOH_R. Then, charge and discharge controller 82 updates SOH_R and FCC held in storage 70 by using the acquired SOH_R and FCC. Charge and discharge controller 82 acquires an SOC estimated by SOC estimating part 810 at each predetermined timing during a charging period. When the acquired SOC reaches an upper limit SOC for stopping charging (for example, SOC 100%), charge and discharge controller 82 determines that the dischargeable capacity has recovered to a desired capacity, controls converter 40, and stops charging of the battery module. At timing before stopping charging, charge and discharge controller 82 updates SOC held in storage 70 by using SOC acquired at this timing.

According to the third exemplary embodiment of the present invention, when SOC estimated by SOC estimating part 810 becomes smaller than the second threshold during the storage period, charge and discharge controller 82 starts charging of battery module 20. At this timing for starting charging, FCC estimating part 814 estimates FCC based on SOH_R calculated by SOH_R calculating part 812. At this timing, charge and discharge controller 82 acquires SOH_R calculated by SOH_R calculating part 812 and FCC estimated by FCC estimating part 814, and then updates SOH_R and FCC stored in storage 70. This makes it possible to estimate FCC while reducing the deviation of the internal resistance from the true value by auxiliary charge, and to further improve estimation accuracy of FCC.

### Fourth Exemplary Embodiment

The fourth exemplary embodiment will be described. The fourth exemplary embodiment describes a modification technique of the technique described in the first to third exemplary embodiments. Items described in the fourth exemplary embodiment are applicable to the first to third exemplary embodiments, and as long as there is no inconsistency, the fourth exemplary embodiment is also applicable to an arbitrary combination of items described in two or more arbitrary exemplary embodiments of the first to third exemplary embodiments.

In general, when a secondary battery is stored in a state close to full charge for a long period of time, degradation of the secondary battery will advance. In order to supply sufficient electric power to load 11 when an abnormality occurs in commercial alternating current power supply 10, it is preferable that the secondary battery is stored in a state of charge close to full charge. Meanwhile, sufficient electric power can be supplied to load 11 even if the secondary battery is stored in a low state of charge, for example, if an abnormality that occurs in commercial alternating current power supply 10 recovers quickly.

According to the fourth exemplary embodiment of the present invention, a fluctuation history of SOC associated with charge or discharge of the secondary battery is stored, and when a fluctuation range of SOC is small, charge and discharge controller 82 changes an upper limit SOC for stopping charge of the secondary battery. This allows inhibition of degradation of the secondary battery while an appropriate dischargeable capacity is secured.

For this purpose, charge and discharge controller 82 acquires an SOC estimated by SOC estimating part 810 at a predetermined interval during discharge of the secondary battery (for example, 10 minutes), and then stores the SOC in storage 70 as the fluctuation history of SOC. At arbitrary timing after finishing discharge and starting charge of the secondary battery, charge and discharge controller 82 reads the fluctuation history from storage 70, and then determines a depth of discharge (DOD) from start to finish of discharge as the fluctuation range of SOC during discharge. Charge and discharge controller 82 changes the upper limit SOC depending on magnitude of DOD. If the DOD is small (for example, DOD is 30%) and the set upper limit SOC is high (for example, SOC 100%), charge and discharge controller 82 changes the upper limit SOC to SOC e % (for example, SOC 50%). Conversely, if the DOD is large (for example, DOD is 50%) and the set upper limit SOC is low (for example, SOC 50%), charge and discharge controller 82 changes the upper limit SOC to SOC f % (for example, SOC 100%).

When changing the upper limit SOC, charge and discharge controller 82 may acquire an SOH_C from SOH_C calculating part 813, and then adjust the upper limit SOC depending on the received SOH_C. For example, when a DOD is 30% and the set upper limit SOC is SOC 100%, charge and discharge controller 82 changes the upper limit SOC to SOC e % on an assumption that SOH_C is 100% in the above description. However, when SOH_C is 90%, the upper limit SOC may be changed to SOC g % (for example, SOC 60%) which is higher than SOC e %. Thus, adjustment of the upper limit SOC depending on SOH_C makes it possible to secure the appropriate dischargeable capacity predicted from a past discharge situation while taking into consideration decrease in chargeable capacity caused by advancement of battery degradation.

In addition, charge and discharge controller 82 may determine a plurality of DODs for each past discharge with reference to the fluctuation history, process the plurality of DODs statistically, and then change the upper limit SOC. For example, charge and discharge controller 82 may calculate an average value of the plurality of DODs (also referred to as average DOD) and change the upper limit SOC based on the average DOD. Charge and discharge controller 82 may calculate a distributed value (distributed DOD) of the plurality of DODs, and adjust the upper limit SOC depending on magnitude of the distributed DOD. By statistically processing the plurality of DODs and changing the upper limit SOC in this way, predictive accuracy from the past discharge situation can be improved, and a more appropriate dischargeable capacity can be secured.

According to the fourth exemplary embodiment of the present invention, charge and discharge controller 82 acquires an SOC estimated by SOC estimating part 810 during discharge and then stores the SOC in storage 70 as the fluctuation history of SOC. Charge and discharge controller 82 reads the fluctuation history from storage 70, and then changes the upper limit SOC. Therefore, the appropriate dischargeable capacity predicted from the past discharge situation can be secured, storage in an unnecessarily high state of charge is avoided, and advancement of battery degradation can be inhibited. In addition, when changing the upper limit SOC, charge and discharge controller 82 acquires an SOH_C from SOH_C calculating part 813, and adjusts the upper limit SOC depending on the received SOH_C. Therefore, it is possible to secure the appropriate dischargeable capacity predicted from the past discharge situation, while taking into consideration decrease in the chargeable capacity caused by the advancement of battery degradation.

The present invention has been described above based on the exemplary embodiments. It will be appreciated by those skilled in the art that these exemplary embodiments are illustrative, and that various modifications are possible in combination of these components and processing processes, and that such modifications are also within the scope of the present invention.

The above exemplary embodiments have described examples in which the SOH_R-SOH_C table includes the amounts of correction for correcting the correspondence of the characteristic function in accordance with the magnitude of SOC when the secondary battery is stored. In this regard, the SOH_R-SOH_C table may include the amounts of correction for correcting the correspondence of the characteristic function in accordance with the magnitude of the terminal voltage when the secondary battery is stored. In this case, the SOH_C fields describe SOH_C to be associated with sohri in combination of the reference values sohci and the m amounts of correction dij (j is an integer from 1 to m) according to the magnitude of the terminal voltage (V1<V2< . . . <Vm−1<Vm) when the secondary battery is stored. Charge and discharge controller 82 stores voltage value Vd received from state detector 81 in storage 70 at timing for stopping discharge or charge of battery module 20. With reference to the SOH_R-SOH_C table, SOH_C calculating part 813 specifies SOH_C at predetermined timing t from SOH_R of each secondary battery received from SOH_R calculating part 812 and voltage value Vd of each secondary battery stored in storage 70.

In addition, the above exemplary embodiments have described examples in which the SOH_R-SOH_C table describes a relationship between SOH_R and SOH_C. In this regard, a graph, equation, etc. may describe the relationship between SOH_R and SOH_C instead of the SOH_R-SOH_C table.

In addition, the above exemplary embodiments have described that, as the SOC when the secondary battery is stored, storage 70 holds the SOC at timing for stopping charge or discharge of battery module 20 and starting storage of battery module 20, and the SOC at timing before stopping charge for recovering the dischargeable capacity of the secondary battery to the desired capacity. In this regard, storage 70 may hold the SOC estimated at arbitrary timing after starting storage of battery module 20 until calculating SOH_R.

Note that the exemplary embodiments according to the present invention may be specified by the items described below.

### [Item 1]

A battery state estimating device including: a first estimating part that estimates internal resistance of a secondary battery at predetermined timing; a first calculating part that calculates a first ratio of the internal resistance of the secondary battery in an initial state to the internal resistance of the secondary battery at the predetermined timing; a storage that stores associated data that associates an internal resistance ratio which is a ratio of the internal resistance of the secondary battery in the initial state to the internal resistance of the secondary battery in a degraded state with a full charge capacity ratio which is a ratio of full charge capacity of the secondary battery in the initial state to the full charge capacity of the secondary battery in the degraded state; and a second estimating part that estimates the full charge capacity of the secondary battery at the predetermined timing based on the first ratio calculated by the first calculating part with reference to the associated data.

### [Item 2]

The battery state estimating device according to item 1, wherein the associated data includes an amount of correction for correcting the association of the internal resistance ratio with the full charge capacity ratio in accordance with magnitude of a charging rate when the secondary battery is stored.

### [Item 3]

A power supply device further including: a secondary battery; a power converter; the battery state estimating device according to item 1 or item 2; and a charge and discharge controller that controls the power converter to charge and discharge the secondary battery, wherein the storage stores a second ratio calculated by a first calculating part last time, when a difference value between a first ratio calculated by the first calculating part and the second ratio stored in the storage becomes larger than a first threshold regarding the difference value during a storage period of the secondary battery, the charge and discharge controller starts discharge of the secondary battery, and the second estimating part estimates a full charge capacity of the secondary battery after discharge of the secondary battery starts during the storage period.

### [Item 4]

The power supply device according to item 3, further including a third estimating part that estimates a charging rate of the secondary battery, wherein when the charging rate estimated by the third estimating part becomes smaller than a second threshold regarding the charging rate during the storage period of the secondary battery, the charge and discharge controller starts charge of the secondary battery, and the second estimating part estimates the full charge capacity of the secondary battery after charge of the secondary battery starts during the storage period.

### [Item 5]

The power supply device according to item 4, wherein the storage stores a fluctuation history of the charging rate of the secondary battery, and the charge and discharge controller changes an upper limit charging rate for stopping charge of the secondary battery with reference to the fluctuation history.

### [Item 6]

The power supply device according to item 5, further including a second calculating part that calculates a third ratio of the full charge capacity of the secondary battery in an initial state to the full charge capacity of the secondary battery at the predetermined timing based on the first ratio calculated by the first calculating part with reference to the associated data, wherein the charge and discharge controller changes the upper limit charging rate for stopping charge of the secondary battery with reference to the fluctuation history and the third ratio.

### INDUSTRIAL APPLICABILITY

The battery state estimating device and power supply device according to the present invention are useful in the backup power supply or the like.

### REFERENCE MARKS IN THE DRAWINGS

10: commercial alternating current power supply
11: load
20: battery module
30: current sensor
31: voltage sensor
32: temperature sensor
40: converter
50: inverter
60: power supply switching unit
70: storage
80: controller
81: state detector
82: charge and discharge controller
810: SOC estimating part
811: internal resistance estimating part
812: SOH_R calculating part
813: SOH_C calculating part
814: FCC estimating part

1. A battery state estimating device comprising:
a first estimating part that estimates internal resistance of a secondary battery at predetermined timing;
a first calculating part that calculates a first ratio of the internal resistance of the secondary battery in an initial state to the internal resistance of the secondary battery at the predetermined timing;
a storage that stores associated data that associates an internal resistance ratio which is a ratio of the internal resistance of the secondary battery in the initial state to the internal resistance of the secondary battery in a degraded state with a full charge capacity ratio which is a ratio of a full charge capacity of the secondary battery in the initial state to the full charge capacity of the secondary battery in the degraded state; and
a second estimating part that estimates the full charge capacity of the secondary battery at the predetermined timing based on the first ratio calculated by the first calculating part with reference to the associated data.

2. The battery state estimating device according to claim 1, wherein the associated data includes an amount of correction for correcting the association of the internal resistance ratio with the full charge capacity ratio in accordance with magnitude of a charging rate when the secondary battery is stored.

3. A power supply device further comprising:
a secondary battery;
a power converter;
the battery state estimating device according to claim 1; and
a charge and discharge controller that controls the power converter to charge and discharge the secondary battery,
wherein the storage stores a second ratio calculated by a first calculating part last time,
when a difference value between a first ratio calculated by the first calculating part and the second ratio stored in the storage becomes larger than a first threshold regarding the difference value during a storage period of the secondary battery, the charge and discharge controller starts discharge of the secondary battery, and
the second estimating part estimates the full charge capacity of the secondary battery after discharge of the secondary battery starts during the storage period.

4. The power supply device according to claim 3, further comprising a third estimating part that estimates a charging rate of the secondary battery,
wherein when the charging rate estimated by the third estimating part becomes smaller than a second threshold regarding the charging rate during the storage period of the secondary battery, the charge and discharge controller starts charge of the secondary battery, and
the second estimating part estimates the full charge capacity of the secondary battery after charge of the secondary battery starts during the storage period.

5. The power supply device according to claim 4, wherein
the storage stores a fluctuation history of the charging rate of the secondary battery, and
the charge and discharge controller changes an upper limit charging rate for stopping charge of the secondary battery with reference to the fluctuation history.

6. The power supply device according to claim 5, further comprising a second calculating part that calculates a third ratio of the full charge capacity of the secondary battery in an initial state to the full charge capacity of the secondary battery at the predetermined timing based on the first ratio calculated by the first calculating part with reference to the associated data,
wherein the charge and discharge controller changes the upper limit charging rate for stopping charge of the secondary battery with reference to the fluctuation history and the third ratio.

7. A power supply device further comprising:
a secondary battery;
a power converter;
the battery state estimating device according to claim 2; and
a charge and discharge controller that controls the power converter to charge and discharge the secondary battery,
wherein the storage stores a second ratio calculated by a first calculating part last time,
when a difference value between a first ratio calculated by the first calculating part and the second ratio stored in the storage becomes larger than a first threshold regarding the difference value during a storage period of the secondary battery, the charge and discharge controller starts discharge of the secondary battery, and
the second estimating part estimates the full charge capacity of the secondary battery after discharge of the secondary battery starts during the storage period.
